(19) United States
(12) Patent Application Publication
(10) Pub. No.: US 2002/0062853 A1
(43) Pub. Date: May 30, 2002

(54) Method of manufacturing a thermoelectric element and a thermoelectric module

(76) Inventors: Takeshi Kajihara, Hiratsuka-city (JP); Kenichi Tomita, Hiratsuka-city (JP)

Correspondence Address: VARNDELL & VARNDELL, PLLC, 106-A S. COLUMBUS ST., ALEXANDRIA, VA, 22314, US

(21) Appl. No.: 09/985,917

(22) Filed: Nov. 6, 2001

(30) Foreign Application Priority Data
Nov. 10, 2000 (JP) 2000-342781

(51) Int. Cl. H01L 35/30; H01L 35/34

(52) U.S. Cl. 136/201; 136/205

(57) ABSTRACT

A method of manufacturing a thermoelectric element capable of varying the temperature characteristics for the figure of merit of the thermoelectric element by changing the conditions during manufacture, the method comprising the steps of mixing and melting by heating starting materials containing substances for controlling the carrier concentration at a predetermined ratio, solidifying the same to prepare an ingot, then powdering the ingot, pressing or press sintering the thus formed powder and further applying hot plastic deformation, in which at least one of the ratio of substances for controlling the carrier concentration or the temperature for carrying out hot plastic working is changed.

### BACKGROUND OF THE INVENTION

1. Field of the Invention

This invention concerns a thermoelectric element that conducts conversion between heat energy and electric energy and a manufacturing method thereof. Further, this invention relates to a thermoelectric module using a thermoelectric element manufactured by the manufacturing method described above.

2. Statement of Related Art

The thermoelectric phenomenon is a generic term of Seebeck phenomenon, Peltier phenomenon and Thomson phenomenon and the element utilizing the phenomenon is referred to as a thermoelectric element, thermocouple, electronic cooling element or the like. The thermoelectric phenomenon is a phenomenon found between different kinds of metals, and semiconductor thermoelectric materials have been obtainable in recent years and conversion efficiency not found in metal materials can be obtained. Since the elements utilizing thermoelectric semiconductor materials are simple in the structure and easy to handle with and can maintain stable characteristics, they have been noted for the use in a wide range of application. Particularly, since they are capable of local cooling or precision temperature control near the room temperature, research and development have been progressed generally for the temperature control of opto-electronics or semiconductor lasers, as well as application use to small-sized refrigerators.

The performance of a thermoelectric element is represented by a figure of merit Z using electrical resistivity ρ, heat conductivity κ and Seebeck coefficient α as below.

Z=α²/ρκ

The Seebeck coefficient takes a positive value in a P-semiconductor material and takes a negative value in an N-semiconductor material. Those thermoelectric elements having high figure of merit Z are desired.

In order to improve the figure of merit of the thermoelectric element, various methods have been developed. For example, Japanese Published Unexamined Patent Application No. 138789/1988, Japanese Published Unexamined Patent Application No. 186299/1996 and Japanese Published Unexamined Patent Application No. 56210/1998 describe that the figure of merit is improved by using extrusion fabrication which is a kind of plastic deformation fabrication as a method of fabrication a thermoelectric element (thermoelectric material, thermoelectric conversion element and sintered thermoelectric semiconductor element). Further, Japanese Published Unexamined Patent Application No. 293276/1992 describes the use of a spherical powdery thermoelectric material for the manufacture of a thermoelectric element.

On the other hand, it has been known that the figure of merit of the thermoelectric element changes greatly depending on the temperature upon use. That is, it has a characteristic that the figure of merit reaches maximum at a specified temperature and goes lower as remote from the temperature. Accordingly, the efficiency can be improved further by making the figure of merit of the thermoelectric element maximum under the working temperature condition.

Heretofore, for changing the temperature at which the figure of merit reaches maximum (hereinafter referred to as peak temperature), the composition of the starting material for the thermoelectric element has been changed greatly. However, since it requires an enormous time for finding a composition suitable to the working temperature, it was not easy to change the composition of the starting material.

Then, in view of the foregoings, this invention intends to provide a method of manufacturing a thermoelectric element of changing the peak temperature for the figure of merit of the thermoelectric element by only changing the manufacturing conditions without changing the composition of the starting material for the thermoelectric element. This invention further intends to provide a thermoelectric module using the thermoelectric element manufactured by the manufacturing method described above.

### SUMMARY OF THE INVENTION

For solving the foregoing subject, a method of manufacturing a thermoelectric element according to this invention comprises the steps of (a) mixing starting materials containing substances for controlling the carrier concentration at a predetermined ratio and melting them by heating, ((b)preparing an ingot by solidifying the heat-melted starting materials), ((c) pulverizing the ingot or powdering the ingot micro-spherical by scattering or spraying the melted ingot and then preparing the powder by sieving them) (d) pressing or press-sintering the powder to prepare a green compact or a sintered body and (e) plastically deforming the green compact or the sintered body at at 350° C. to 550° C. in order to orient the crystal grains into a crystal direction that provides high figure of merit).

In this method, thermoelectric elements which have different temperature character are manufactured by changing the ratio of substances for controlling the carrier concentration in (a), the plastically deforming temperature in (e) at least one of them. Further, for removing strains from the plastically deformed thermoelectric materials, thermoelectric elements which have different thermoelectric character are manufactured by employing anneal process at 300 to 400° C., within 24 hours(f).

Further, a thermoelectric module according to this invention is constituted by laminating a first group of thermoelectric elements manufactured by the manufacturing method as described above and a second group of thermoelectric elements which are manufactured by the manufacturing method as described above and have different temperature character from the first group through insulative plates.

According to this invention, the peak temperature for the figure of merit of the thermoelectric element can be changed by changing the conditions for the manufacturing method without changing the composition of the starting materials. Accordingly, by selectively using thermoelectric elements of different peak temperatures of the figure of merit for each stage, a multi-stage module having better performance than usual can be attained.

### DESCRIPTION OF THE ACCOMPANYING DRAWINGS

FIG. 1 is a flow chart showing a method of manufacturing a thermoelectric element in a first embodiment according to this invention;

FIG. 2 shows the temperature dependence of figure of merit of thermoelectric element which is manufactured by the manufacturing method related to the first embodiment in this invention.

FIG. 3 is a flow chart showing a method of manufacturing a thermoelectric element in a second embodiment according to this invention;

FIG. 4 shows the temperature dependence of figure of merit of thermoelectric element which is manufactured by the manufacturing method related to the second embodiment in this invention.

FIG. 5 is a flow chart showing a method of manufacturing a thermoelectric element in a third embodiment according to this invention;

FIG. 6 shows the temperature dependence of figure of merit of thermoelectric element which is manufactured by the manufacturing method related to the third embodiment in this invention. and

FIG. 7 shows a cross section of thermoelectric module related to one embodiment in this invention.

### DESCRIPTION OF PREFERRED EMBODIMENTS

This invention is to be explained by way of preferred embodiments with reference to the drawings. Throughout the drawings, identical constituent components carry the same reference numerals for which duplicate explanations are to be omitted.

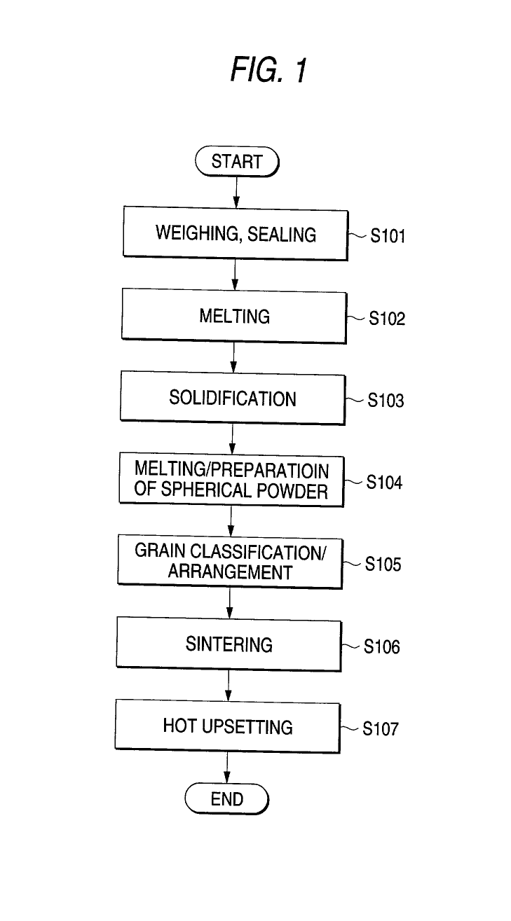

FIG. 1 is a flow chart showing a method of manufacturing a thermoelectric element in a first embodiment according to this invention. This embodiment has a feature of varying a temperature at which the figure of merit reaches a peak by changing the temperature in hot plastic working.

At first, starting materials having a predetermined composition are weighed and sealed in an ampule (step S101). In this embodiment, as the starting material for a P-type element (P-semiconductor), antimony (Sb), bismuth (Bi) and tellurium (Te) were used and weighed so as to provide a stoichiometric ratio of Bi_{0.4}Sb_{1.6}Te₃.

Then, after melting and mixing the starting materials in step S102, the molten starting materials are solidified to prepare an ingot at step S103. Then, the ingot is powderized (step S104). For example, a spherical powder can be prepared by dropping droplets of the starting material on a rotating disk and scattering them, or spraying droplets of the starting material. Further, the powder was put to a sieve of 100 mesh or 400 mesh to arrange so as to provide a grain size of 38 μm to 150 μm (step S105).

Then, the arranged powder is put in a sintering die and powder-sintered by a hot pressing apparatus at a sintering temperature of 500° C. and under a pressure of 750 kg/cm² (step S106). Further, the plastic deformation was employed for the sintered material at 350° C. to 550° C. In this embodiment, hot upsetting is employed at a temperature of 400° C. for one of the sintered material and at a temperature of 500° C. for another of the sintered material (step S107).

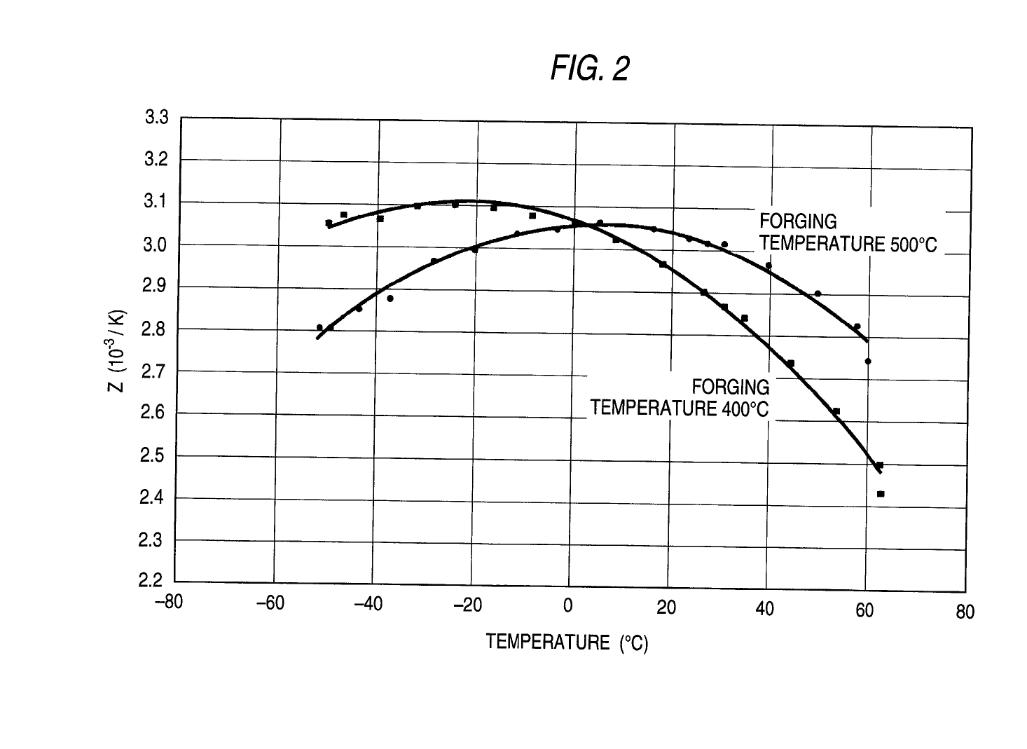

FIG. 2 shows the temperature dependence of figure of merit of thermoelectric element which is manufactured by the manufacturing method related to the embodiment in this invention) The temperature at which the figure of merit reaches a maximum (hereinafter referred to as a peak temperature) is around −25° C. for the specimen applied to hot upsetting at 40 0° C., whereas the peak temperature of the figure of merit is around +10° C. for the specimen applied to hot upsetting at 500° C.

As described above, even when starting materials of an identical composition are used, the peak temperature for the figure of merit can be varied by changing the temperature of plastic working.

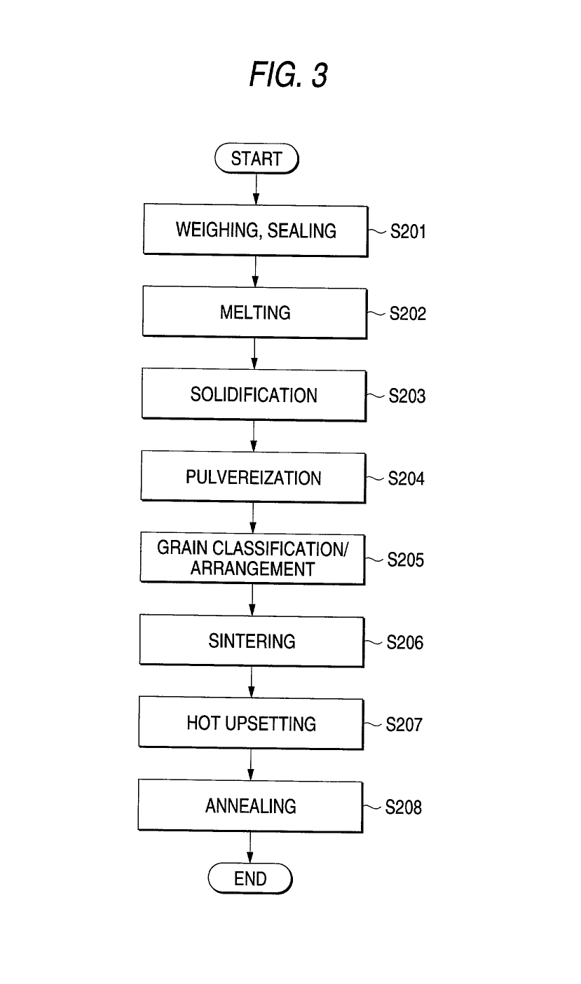

Then, the method of manufacturing the thermoelectric element in a second embodiment according to this invention is to be explained with reference to FIG. 3. FIG. 3 is a flow chart showing the method of manufacturing a thermoelectric element in the second embodiment according to this invention. This invention has a feature of varying the temperature at which the figure of merit reaches a peak by applying anneal for the plastically deformed thermoelectric element or not.

At first, starting material having a predetermined composition are weighed and sealed in an ampule (step S201). Also in this embodiment, as the starting materials for the P-type element, antimony (Sb), bismuth (Bi) and Tellurium (Te) were weighed so as to provide a stoichiometrical ratio of Bi_{0.4}Sb_{1.6}Te₃.

Then, after melting and mixing the starting materials at step S202, the molten starting materials are solidified to prepare an ingot at step S203. Then, the ingot is powderized at step S204. In this embodiment, the ingot was pulverized by a stamp mill or ball mill. Further, the powder was put to a 100 mesh or 400 mesh sieve to be arranged such that the grain size is 38 μm to 150 μm.

Then, the arranged powder was put in a sintering die and powder-sintered by a hot pressing apparatus at a sintering temperature of 500° C. and under a pressure of 750 kg/cm² (step S206). Further, the sintered product is applied with hot upsetting under a temperature of 500° C. (step S207). Finally, for a part of the forged sample, annealing was applied under the temperature of 350° C. for 10 hours (step S208).

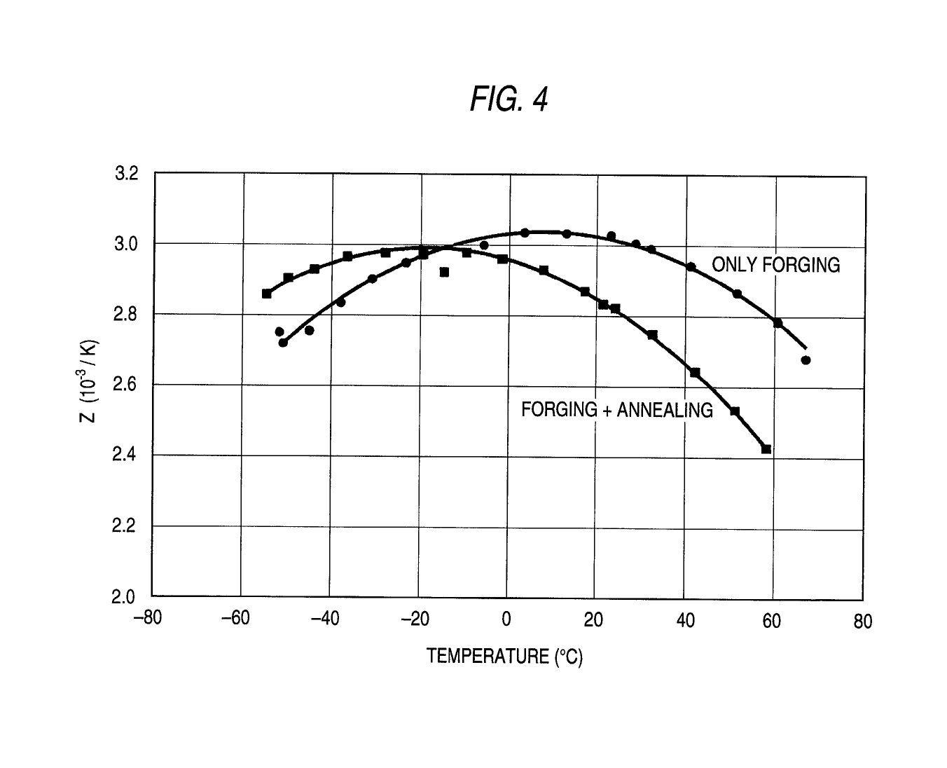

FIG. 4 shows the temperature dependence of figure of merit of thermoelectric element which is manufactured by the manufacturing method related to the embodiment in this invention. The peak temperature of the figure of merit was around +10° C. in the specimen not applied with annealing, whereas the peak temperature for the figure of merit is around −20° C. in the specimen applied with annealing.

As described above, even when the starting materials having an identical composition is used, the peak temperature of the figure of merit can be changed by employing anneal or not after plastic working.

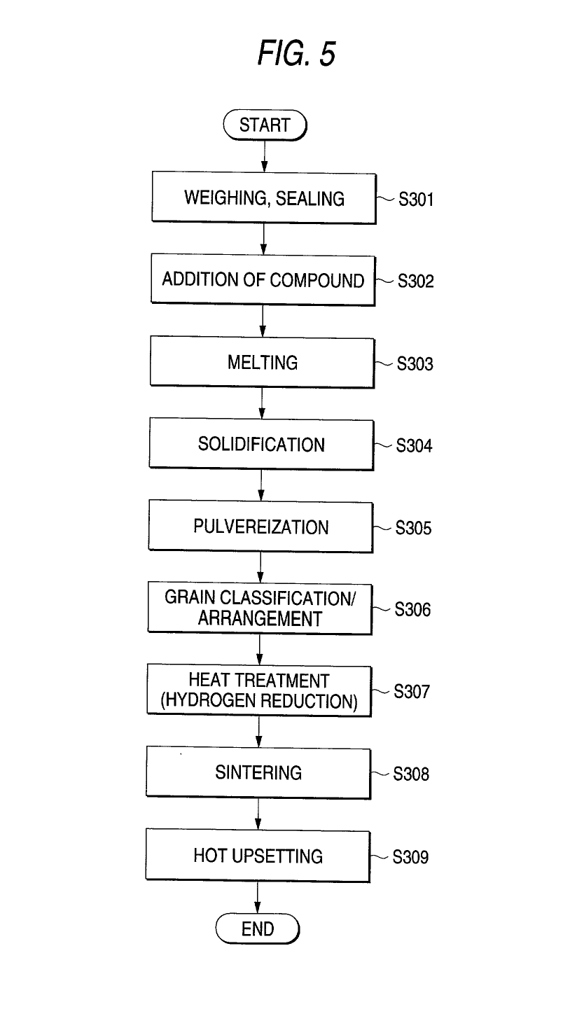

Then, a method of manufacturing a thermoelectric element in a third embodiment according to this invention is to be explained with reference to FIG. 5. FIG. 5 is a flow chart showing a method of manufacturing a thermoelectric element in the third embodiment according to this invention. This embodiment has a feature in varying the temperature where the figure of merit reaches a peak by adding the amount of impurities for controlling the carrier concentration.

At first, starting materials having a predetermined composition were weighed or sealed in an ampule (step S301) In this embodiment, as a starting material for the N-type element (N-semiconductor), bismuth (Bi), tellurium (Te) and selenium (Se) were weighed so as to provide a stoichiometrical ratio of Bi₂Te_{2.7}Se_{0.3} and, for controlling the carrier concentration further, a halogen compound is preferably added at a ratio within 0.1 wt %. In this embodiment, a halogen compound in an amount 0.09 wt % is added to one of the specimen, while a halogen compound is added by 0.06 wt % in another specimen.

Then, after melting and mixing the starting materials at step S302, the molten starting materials are solidified to prepare an ingot at step S303. Then, the ingot is powderized. In this embodiment, the molten material was pulverized by a stamp mill or a ball mill. The powder was put to 150 mesh-400 mesh sieves and arranged such that the grain size is 38 μm to 106 μm (step S305).

Then, a predetermined volume of the arranged powder is supplied into a glass ampoule of a predetermined volume under evacuation and, after charging hydrogen and sealing at 0.9 atm, it was subjected to a heat treatment in a furnace heated to 350° C. for 10 hours to conduct hydrogen reduction (step S307) Then, the hydrogen reduced powder was put in a sintering die and put to powder sintering in an argon atmosphere at a sintering temperature of 500° C. and under a pressure of 750 kg/cm² (step S308). Further, the sintered product was applied with hot upsetting at a temperature of 450° C. (step S309)

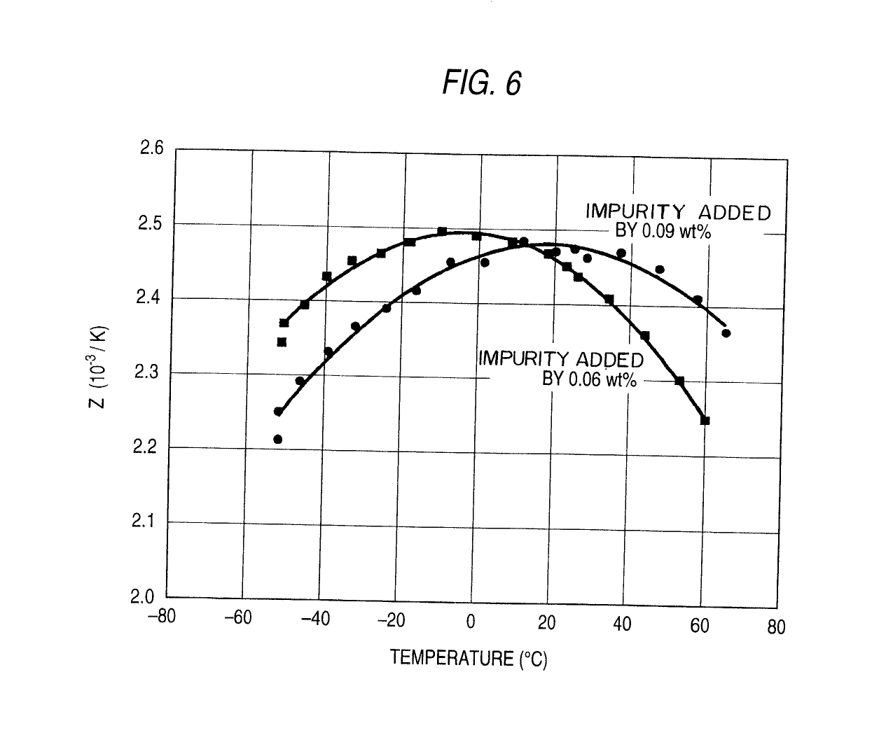

FIG. 6 shows the temperature dependence of figure of merit of thermoelectric element which is manufactured by the manufacturing method related to the embodiment in this invention. The peak temperature of the figure of merit is around −3° C. for a specimen with addition of halogen compound of 0.06 wt %, whereas the peak temperature of the figure of merit is around +20° C. for a specimen with addition amount of 0.09 wt %.

As described above, even when starting material having the identical composition is used, the peak temperature of the figure of merit can be varied by changing the amount of the added impurities.

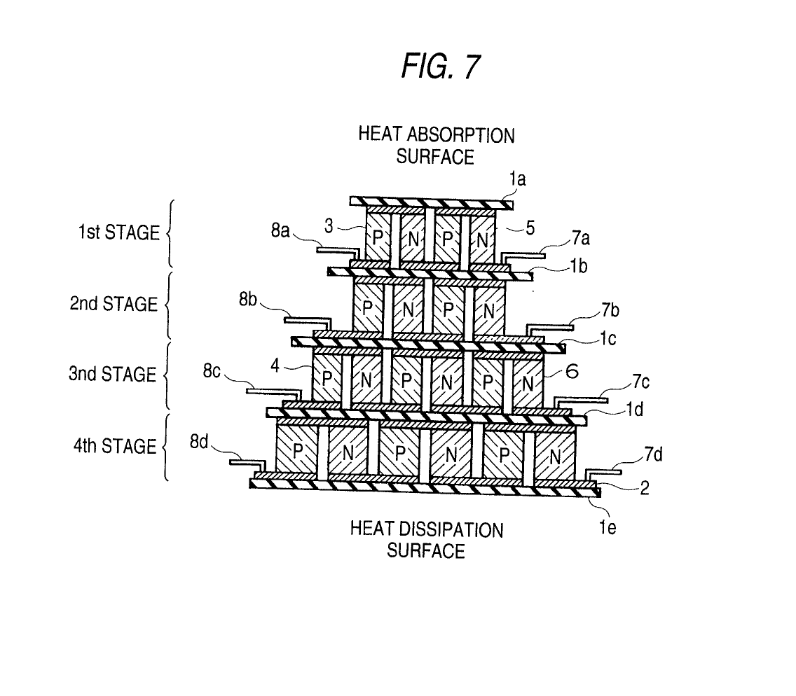

Then, a thermoelectric module in one embodiment according to this invention is to be explained with reference to FIG. 7. FIG. 7 shows a cross section of thermoelectric module related to one embodiment in this invention.

A thermoelectric module shown in FIG. 7 is prepared by forming a PN element pair by connecting a P-element (P-semiconductor) and an N-element (N-semiconductor) by way of an electrode 2, further, a plurality of PN element pairs are connected in serial and they are stacked alternately with plural ceramic substrates 1a to 1e to form a four stage module. In the series circuit of the PN element pairs constituting each stage, current introduction terminals (positive electrode) 7a to 7d are connected respectively to the N-type element at one end, while current introduction terminals (negative electrode) 8a to 8d are connected respectively to the P-type element at the other end. When current is applied from the current introduction terminals (positive electrode) 7a to 7d by way of the serial circuit of the PN element pairs to the current introduction terminals (negative electrode) 8a to 8d by applying a voltage between the current introduction terminals 7a and 8a and 7b and 8b - - - respectively, heat is absorbed on the side of the ceramic substrates above, while heat is emitted to the ceramic substrates below in each of the stages.

In the multi-stage thermoelectric module as described above, the temperature of the thermoelectric elements is lowered from the lower stage to the upper stage. Accordingly, if thermoelectric elements having optimal peak temperature are used for each of the stages, a thermoelectric module of better heat conversion efficiency than usual can be attained. Then, the thermoelectric module in this invention, P-type or N-type thermoelectric elements at a relatively higher peak temperature are used for the lower stage and P-type or N-type thermoelectric elements at a relatively lower peak temperature are used for the upper stage to form a laminate structure.

A thermoelectric module was manufactured by this invention method and the experiment which compares to the former multi-stage thermoelectric module was done. As examples, P-type elements (P-type elements 3 on the lower temperature side) applied with annealing and P-type elements (P-type elements 4 on higher temperature side) not applied with annealing manufactured by the manufacturing method in the second embodiment according to this invention and N-type elements (N-type elements 5 on low temperature side) with addition of 0.06 wt % impurities and N-type elements (N-type elements 6 on high temperature side) with addition of 0.09 wt % impurities were used. In FIG. 7, assuming the uppermost stage as a first stage, the p-type elements 3 on the lower temperature side and the N-type elements 5 on the lower temperature side are disposed at the first stage and the second stage and the P-type elements 4 on the higher temperature side and the N-type element 6 at the higher temperature side are arranged in third stage and fourth stage.

Further, for comparison, the former multi-stage thermoelectric module was prepared by using P-type and N-type elements which are prepared from the ingot of an equal composition for the starting materials from the first stage to the forth stage.

When an experiment was done at the temperature of the heat dissipation surface of 300K by using the thermoelectric module which is prepared by this invention method and the former thermoelectric module, the temperature at the heat absorption surface of the former thermoelectric module was 186K, whereas the temperature at the heat absorption surface was 178K in the thermoelectric module which is prepared by this invention method. That is, there was a temperature difference as much as 8K between both of them to demonstrate that the performance of the thermoelectric module according to this invention is excellent.

Further, for the thermoelectric module related to this invention, the thermoelectric element manufactured by the manufacturing method in the first embodiment related to this invention can also be used. Further, the thermoelectric module related to this invention can be prepared by using a manufacturing method related to the first to third embodiments in this invention, manufacturing thermoelectric elements having different temperature characteristics, varying the temperature of the hot plastic working, or whether employing anneal or not, or varying the amount of the added impurities.

As has been described above, according to this invention, the temperature at which the figure of merit of the thermoelectric element reaches maximum (peak temperature) can be varied by changing the conditions in the manufacturing method without changing the composition of the starting materials. Accordingly, a multi-stage module which has more excellent performance than the former can be attained by selectively using the thermoelectric elements which has different peak temperature of figure of merit for each stage.

What is claimed is:

1. A method of manufacturing a thermoelectric element comprising the steps of
(a) mixing starting materials containing substances for controlling the carrier concentration at a predetermined ratio and melting them by heating,
(b) preparing an ingot by solidifying the heat-melted starting materials,
(c) pulverizing the ingot or powdering the ingot to micro-spherical by scattering or spraying the melted ingot, and then preparing the powder by sieving them,
(d) pressing or press-sintering the powder to prepare a green compact or a sintered body, and
(e) plastically deforming the green compact or the sintered body at at 350° C. to 550° C. in order to orient the crystal grains into a crystal direction that provides high figure of merit.

2. A manufacturing method as defined in claim 1, wherein thermoelectric elements which have different temperature characters are manufactured by changing at least any one of the ratio of substances for controlling the carrier concentration in step (a) and the plastically deforming temperature in step (e).

3. A manufacturing method as defined in claim 1, further comprising the step of
(f) employing anneal process at 300 to 400° C., within 24 hours, for removing the strain in the plastically deformed thermoelectric materials and manufacturing thermoelectric elements which have different thermoelectric characters.

4. A thermoelectric module constituted by laminating a first group of thermoelectric elements manufactured by the manufacturing method as defined in claim 1, 2 or 3 and a second group of thermoelectric elements manufactured by the manufacturing method as defined in claim 1, 2 or 3, and having a different temperature character from that of the first group through insulative plates.
